(19) United States
(12) Patent Application Publication
(10) Pub. No.: US 2025/0370064 A1
(43) Pub. Date: Dec. 4, 2025

(54) Fully Automated Diagnostic System and Method for Fault Detection in Ratio-Metric Signal Paths

(71) Applicant: PI Semiconductor (US) Limited, San Jose, CA (US)

(72) Inventors: George R. Kunnen, Chandler, AZ (US); Brian A. Miller, Gilbert, AZ (US); Antoine D. Fifield, Mesa, AZ (US); Daniel D. Alexander, Mesa, AZ (US); Shyamsunder Ramanathan, Bangalore (IN)

(73) Assignee: PI Semiconductor (US) Limited, San Jose, CA (US)

(21) Appl. No.: 18/676,616

(22) Filed: May 29, 2024

(51) Int. Cl. G01R 31/52; G01R 31/26; H03K 17/082

(52) U.S. Cl. CPC G01R 31/52; G01R 31/2607; H03K 17/0822

(57) ABSTRACT

A fault detection circuit has multiple inputs adapted for a resistance network, and a current source circuit selectively coupled to the inputs to detect a fault condition. The current source circuit has a first current source, a first switching circuit between the first current source and a first node, a first resistor between the first node and a first input, a second switching circuit between the first input and a power supply conductor, and a third switching circuit between the first node and a second node. The current source circuit further has a second current source, a fourth switching circuit between the second current source and a third node, a second resistor between the third node and a second input, a fifth switching circuit between the second input and the power supply conductor, and a sixth switching circuit between the third node and the second node.

### FIELD OF THE INVENTION

The present invention relates in general to automated fault detection and diagnostics, more particularly, to a system and method for sensing signal path faults present on an array of pins used for measuring analog voltage signals.

### BACKGROUND OF THE INVENTION

A battery can be used in a wide spectrum of applications, including in automotive, commercial, and personal transportation, shipping, military, and aerospace. For example, a battery can power an electric or hybrid automobile. Other battery applications include high-voltage battery packs, electric bikes, super-cap systems, battery-powered tools, and battery-backup systems or uninterruptable power supplies (UPS). The battery is an integral and necessary part of the operation of the electric or hybrid automobile. If the battery fails, the automobile will likely cease normal operation, stranding the occupants in a potentially unsafe situation. It is important for the occupants to know if the battery has failed or is about to fail before starting out on any trip or journey. Most, if not all, modern electric and hybrid vehicles have a battery management system (BMS) to monitor the health and status of the battery and give a warning of a potential problem. The temperature of the battery is a common condition for the BMS to monitor, as a battery in trouble will typically generate excess heat.

To monitor battery temperature, a negative temperature coefficient (NTC) thermistor is typically located in proximity to or in contact with the battery to provide an accurate temperature measurement. The NTC thermistor is connected by cabling to the BMS to take readings of the battery temperature, perform diagnostics, and report battery status to the operator of the automobile. However, if there is an electrical fault in the wiring, such as a short circuit or electrical open, anywhere in the NTC thermistor, cabling, and/or BMS, then battery monitoring system becomes unreliable or unusable. Any actual or pending fault condition in the battery may not be properly reported because the battery monitoring system itself is faulty.

### BRIEF DESCRIPTION OF THE DRAWINGS

FIG. 1 illustrates an electric vehicle containing a battery and battery management system and associated cabling;

FIGS. 2a-2c illustrate a semiconductor wafer with a plurality of semiconductor die separated by a saw street;

FIG. 3 illustrates a block diagram of a battery management system;

FIG. 4 illustrates a schematic diagram of a battery management system with a fault detection circuit;

FIG. 5 illustrates a schematic diagram of an electric switching circuit;

FIG. 6 illustrates a schematic diagram of the fault detection circuit in a first test mode with no fault;

FIG. 7 illustrates a schematic diagram of the fault detection circuit in the first test mode with a first fault;

FIG. 8 illustrates a schematic diagram of the fault detection circuit in the first test mode with a second fault;

FIG. 9 illustrates a schematic diagram of the fault detection circuit in a second test mode;

FIG. 10 illustrates a schematic diagram of the fault detection circuit in a third test mode;

FIG. 11 illustrates a schematic diagram of the fault detection circuit in a fourth test mode; and

FIG. 12 illustrates a schematic diagram of another embodiment of the fault detection circuit;

FIG. 13 illustrates a schematic diagram of the fault detection circuit from FIG. 12 in a first test mode with a first fault;

FIG. 14 illustrates a schematic diagram of the fault detection circuit from FIG. 12 in the first test mode with a second fault;

FIG. 15 illustrates a schematic diagram of the fault detection circuit from FIG. 12 in a second test mode;

FIG. 16 illustrates a schematic diagram of the fault detection circuit from FIG. 12 in a third test mode;

FIG. 17 illustrates a schematic diagram of the fault detection circuit from FIG. 12 in a fourth test mode; and

FIG. 18 illustrates a flow chart of the fault detection process.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, those skilled in the art will appreciate that the description is intended to cover alternatives, modifications, and equivalents as may be included within the spirit and scope of the invention as defined by the appended claims and the claims' equivalents as supported by the following disclosure and drawings.

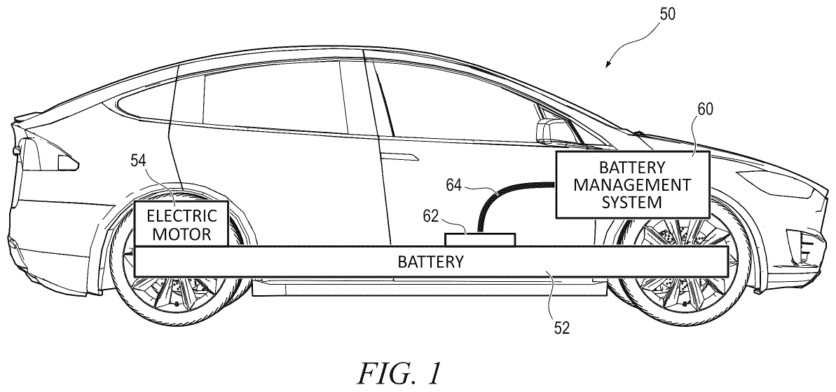

A battery is useful in automotive, commercial, and personal transportation, shipping, military, and aerospace. The battery provides a portion or all of the energy to power the vehicle. For example, electric or hybrid automobile 50 uses battery 52 to power electric motor 54 and propel the automobile, as shown in FIG. 1. Battery 52 is an integral and necessary part of the operation of automobile 50. If battery 52 fails, automobile 50 will likely cease normal operation, stranding the occupants in a potentially unsafe situation. It is important for the occupants to know if the battery has failed or is about to fail before starting out on any trip or journey. Other battery applications include high-voltage battery packs, electric bikes, super-cap systems, battery-powered tools, and battery-backup systems or UPS.

Electric or hybrid automobile 50 includes BMS 60 to monitor the health and status of battery 52 and give a warning of a potential problem. The temperature of battery 52 is a common condition for BMS 60 to monitor, as a battery in trouble will typically generate excess heat. To monitor battery temperature, NTC thermistor array 62 is located in proximity to or in contact with battery 52 to provide an accurate temperature measurement. NTC thermistor array 62 is connected by cabling 64 to battery management system 60 to take readings of the battery temperature, perform diagnostics, and report battery status to the operator of automobile 50. It is important to detect an electrical fault in the wiring, such as a short circuit or open circuit, anywhere in the NTC thermistor, cabling, and/or BMS.

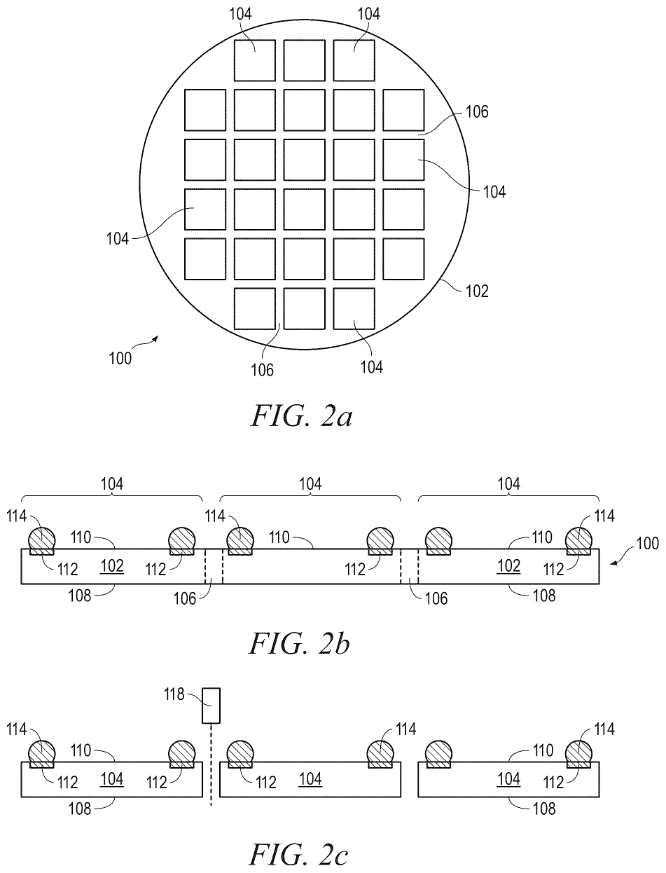

BMS 60 includes multiple semiconductor devices to perform testing, monitoring, diagnostics, and reporting of battery conditions. FIG. 2a shows semiconductor wafer or substrate 100 with a base substrate material 102, such as silicon (Si), SiC, cubic silicon carbide (3C-SiC), germanium, aluminum phosphide, aluminum arsenide, gallium arsenide, gallium nitride, indium phosphide, diamond, and all families of III-V and II-VI semiconductor materials for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 2b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. In one embodiment, analog and digital circuits used in BMS 60 are formed on active surface 110 of semiconductor die 104 to provide, in part, fault detection.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 2c, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation,

Semiconductor die 104 can be contained in a semiconductor package, such as TO220, T0247, decawat package (DPAK), double decawat package (D2PAK), TSON, micro leadframe package (MLP), dual flat no-leads (DFN), and other packages suitable for mounting to a printed circuit board (PCB) within BMS 60.

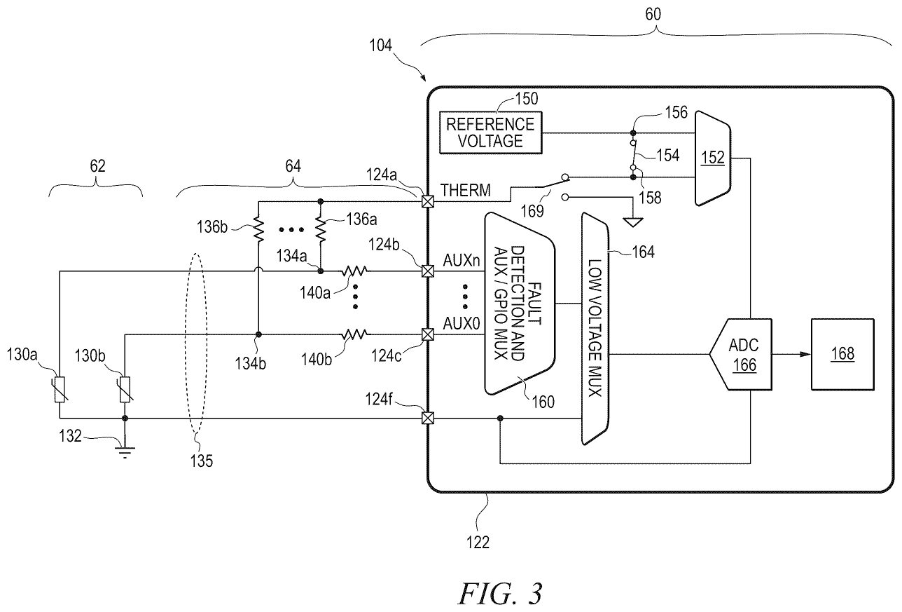

FIG. 3 illustrates further detail of NTC thermistor array 62, cabling 64, and a portion of BMS 60. As defined herein, cabling 64, in concert with FIG. 1, includes those components disposed between thermistor array 62 and BMS 60, in particular, wiring harness 135 and the resistor divider network 136a and 136b and 140a and 140b. The individual NTC resistors 130a and 130b represent thermistor array 62. NTC thermistor array 62 can have multiple monitoring points on battery 52, hence there are multiple NTC resistors in the NTC thermistor array, one for each monitoring point. In one embodiment, thermistor array 62 has n-number of NTC resistors 130, where n is an integer 8. NTC resistors 130a and 130b may each have a value of hundreds of ohms. NTC resistors 130a and 130b are coupled between nodes 134a and 134b and power supply terminal 132 operating at ground potential, respectively. Cabling 64 includes resistors 136a and 136b and resistors 140a and 140b logically disposed within thermistor wiring harness 135 and operating as voltage dividers for the voltage generated across NTC resistors 130a and 130b in response to the temperature being monitored at various points on and around battery 52. Resistor 136a and resistor 140a formed the voltage divider for NTC resistor 130a, resistor 136b and resistor 140b formed the voltage divider for NTC resistor 130b, and so on. There would be a set of voltage divider resistors like 136a, 140a for each NTC resistor 130. Resistors 136a and 136b may have a value of 10 Kohms, and resistors 140a and 140b may have a value of 1.0 Kohms.

BMS 60 is shown with the analog and digital circuits as disposed on semiconductor die 104, although it is understood that the BMS has multiple semiconductor die performing various functions. The subject matter of the present invention is concerned with the analog and digital circuits, in particular fault detection and auxiliary general purpose digital input/output (GPIO) multiplexor 160, as disposed on semiconductor die 104 in FIG. 3. Line 122 represents the physical boundary of semiconductor die 104. Terminals 124a-124f are external terminals of semiconductor die 104, e.g., bumps 114. Resistors 140a and 140b are shown as being coupled to terminals 124b and 124c.

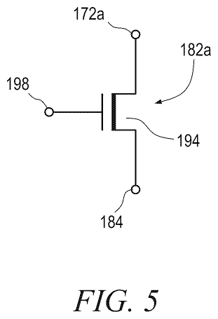

Semiconductor analog and digital circuits located within active area 110 of semiconductor die 104 include reference voltage 150 providing a fixed and regulated positive reference voltage to node 156. Node 156 is coupled through electric switching circuit 154 to node 158. Electric switching circuit 154 can be implemented using transistor 194, as described in FIG. 5. Auxiliary reference selector multiplexor 152 has first and second inputs coupled to nodes 156 and 158. Semiconductor analog and digital circuits located within active area 110 of semiconductor die 104 also include fault detection and auxiliary GPIO multiplexor 160, low voltage multiplexor 164, analog to digital converter (ADC) 166 and auxiliary register 168. Fault detection and auxiliary GPIO multiplexor 160 has multiple inputs coupled to terminals or pins 124b and 124c, labeled as AUX0-AUXn.

FIG. 3 pertains to the “normal use case/mission mode” of the circuit where the NTC network is used for temperature measurement. Terminal 124a, also labeled as THERM, is coupled through electric switching circuit 169 to either the reference voltage from node 158 or power supply terminal 132 operating at ground potential. During normal mission mode where the NTC network measures temperature, terminal 124a is coupled to node 158. During fault detection diagnostic, as discussed infra, terminal 124a is coupled to ground potential.

There is one AUX channel or input for each NTC resistor 130. The output of fault detection and auxiliary GPIO multiplexor 160 is coupled to a first input of low voltage multiplexor 164. A second input of low voltage multiplexor 164 is coupled to terminal 124f receiving ground potential from power supply terminal 132. ADC 166 receives an analog signal from low voltage multiplexor 164 and provides a digital signal to auxiliary register 168. ADC 166 is also coupled to an output of auxiliary reference selector multiplexor 152 to receive the reference voltage, and terminal 124f to receive ground potential from power supply terminal 132.

BMS 60 uses a precision set of auxiliary measurement channels or pins AUX0-AUXn as a part of an integrated battery stack monitoring system. In addition to having the ability to be configured as GPIO, the AUX0-AUXn channels will often be configured to measure either temperature or voltage as part of the monitoring system's state-of-health diagnostics. The integrated battery stack monitor uses at least one ADC to provide a digital representation of the voltage present on each of the AUX0-AUXn channels.

In the more common case of a temperature measurement application, an auxiliary channel's input voltage (V_{AUXn}) may be generated by a resistor divider circuit 136, 140 including a fixed resistive pull-up resistor 136 going to a reference voltage at terminal 124a and NTC resistor 130 to an analog ground. Referring to the example ratio-metric application circuit in FIG. 3, the resulting value of V_{Auxn} is determined by equation (1):

$${V}_{AUXn} = {V}_{THERMn} ( \frac{{R}_{NTCn}}{{R}_{THERMn} + {R}_{NTCn}} )$$

where:
RNTC is the resistance of thermistors 130a/130b,
VTHERM is the voltage on terminal 124a,
RTHERM is the resistance of resistors 136a/136b, and
VAUXn is the voltage at terminals 124b-124c.

In an NTC resistor, the resistance can be defined as a function of temperature T (in units of Kelvin), as in equation (2):

$${R}_{NTCn} ( T ) = {R}_{0} * {e}^{β * ( \frac{1}{T} - \frac{1}{{T}_{0}} )} \qquad ( 2 )$$

where R₀ is the resistance of the R_{NTC} at room temperature T₀ (273.15 Kelvin), and
β is a constant specific to the chosen NTC resistor (typically in the 3000 to 5000 Kelvin range).

Since the fixed values of V_{THERM}, R_{THERMn}, are known, as well as the temperature characteristics of R_{NTCn}, it is possible to calculate the temperature inherent to the NTC resistor by means of acquiring the ADC conversion of V_{Auxn}. If, however, any faults such as broken wires or shorted pins exist on the AUX0-AUXn channels, the temperature measurement will provide erroneous results for the state of health monitoring system. Thus, for a BMS application it is necessary to ensure the highest level of functional safety coverage, and as a result, it is important for the system to detect, diagnose, and report external faults, such as port-to-port shorts or broken wires.

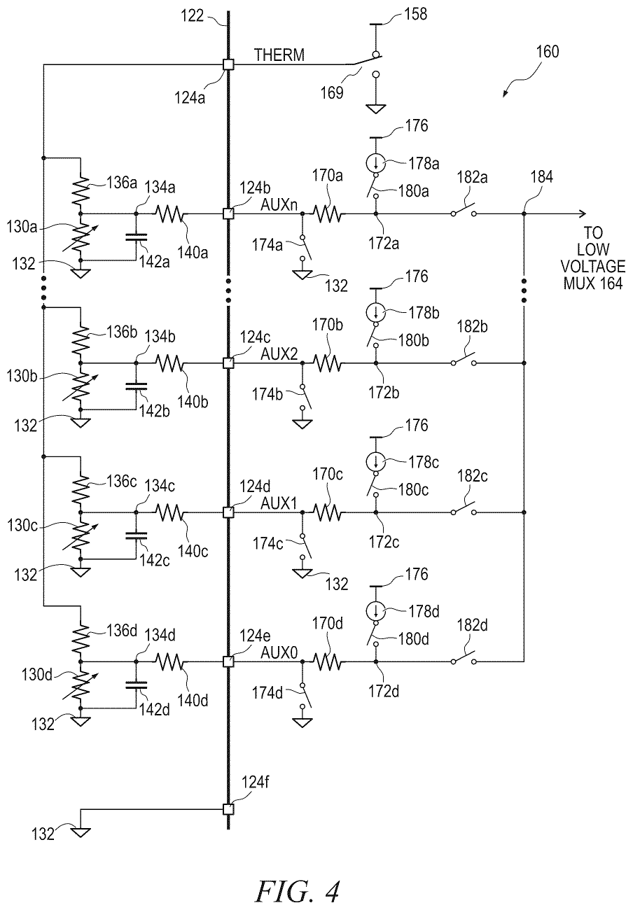

FIG. 4 illustrates further detail of fault detection and auxiliary GPIO multiplexor 160, as well as NTC resistors 130 from thermistor array 62 and voltage divider resistor 136, 140 from cabling 64. Elements or components having a similar function as used herein are assigned the same reference number. Capacitors 142a-142d are coupled between node 134a-134d, respectively, and power supply terminal 132. Terminals 124d and 124e are added, with respect to FIG. 3, to show four AUX channels in operation. Terminal 124a is coupled through electric switching circuit 169 to either the reference voltage from node 158 or power supply terminal 132 operating at ground potential. During normal mission mode where the NTC network measures temperature, terminal 124a is coupled to node 158. During fault detection diagnostic, terminal 124a is coupled to ground potential.

Fault detection and auxiliary GPIO multiplexor 160 performs fault detection in multiple test modes. The analog circuits fault detection and auxiliary GPIO multiplexor 160 allow for multiple test modes, one test mode associated with each AUX channel. For example, to support a first test mode, resistor 170a is coupled between terminal 124b and node 172a. Electric switching circuit 174a is coupled between terminal 124b and power supply terminal 132. Current source 178a, as referenced to power supply conductor 176 operating at a positive potential, sources a fixed current. Electric switching circuit 180a is coupled between current source 178a and node 172a. Electric switching circuit 182a is coupled between node 172a and node 184. Node 184 is coupled to a first input of low voltage multiplexor 164.

To support a second test mode of the fault detection, resistor 170b is coupled between terminal 124c and node 172b. Electric switching circuit 174b is coupled between terminal 124b and power supply terminal 132. Current source 178b, as referenced to power supply conductor 176 operating at a positive potential, sources a fixed current. Electric switching circuit 180b is coupled between current source 178b and node 172b. Electric switching circuit 182b is coupled between node 172b and node 184.

To support a third test mode of the fault detection, resistor 170c is coupled between terminal 124d and node 172c. Electric switching circuit 174c is coupled between terminal 124d and power supply terminal 132. Current source 178c, as referenced to power supply conductor 176 operating at a positive potential, sources a fixed current. Electric switching circuit 180c is coupled between current source 178c and node 172c. Electric switching circuit 182c is coupled between node 172c and node 184.

To support a fourth test mode of the fault detection, resistor 170d is coupled between terminal 124e and node 172d. Resistors 170a-170d provide ESD ballast resistance and may have a value of 300 ohms. The value of resistors 170a-170d should be minimized to reduce the resistance shared between AUX measurement path 172 to terminal 124 and the test current path (output of current source 180 to terminal 124) going to the AUX pin. Another approach would be to implement a separate Kelvin connection from the test current switch 180 to the AUX pin 124. Electric switching circuit 174d is coupled between terminal 124e and power supply terminal 132. Current source 178d, as referenced to power supply conductor 176 operating at a positive potential, sources a fixed current. In one embodiment, current sources 178a-178d have a fixed current of 100 microamps (μA). Electric switching circuit 180d is coupled between current source 178d and node 172d. Electric switching circuit 182d is coupled between node 172d and node 184.

Electric switching circuits, as noted herein, including electric switching circuits 169, 174a-174d, 180a-180d, and 182a-182d, can be implemented with a complementary metal oxide semiconductor (CMOS) transistor 194, as shown in FIG. 5. For electric switching circuit 182a, as an example, the drain of transistor 194 is coupled to node 172a and the source of the transistor is coupled to node 184. The gate terminal 198 of transistor 194 receives a control signal to turn the transistor on and off, i.e., to close and open the electric switch.

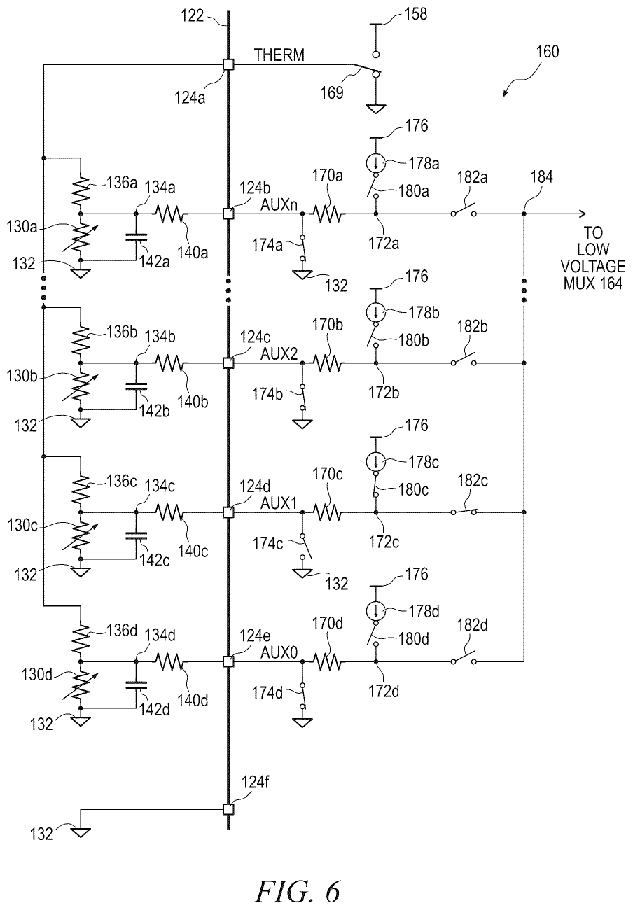

Consider a fault detection test of NTC thermistor array 62, cabling 64, and BMS 60, starting with a test mode for channel AUX1. Electric switch circuit 169 may be set to ground terminal 124a thereby pulling all connected NTC networks and AUX pins resistively to ground. Electric switching circuits 182a, 182b, 182c, and 182d are all open. Electric switching circuit 182c is closed, as shown in FIG. 6. Electric switching circuit 174c is open and electric switching circuits 174a, 174b, and 174d are closed. Electric switching circuit 180c is closed and electric switching circuits 180a, 180b, and 180d are open. This configuration will perform fault detection in a test mode for channel AUX1 involving NTC resistor 130c, voltage divider resistors 136c, 140c, terminal 124d, resistor 170c, current source 178c, electric switching circuit 180c, and electric switching circuit 182c, as well as all cabling, wiring, traces, and conduits between these devices. The configuration disables fault detection for channels AUX0, AUX2, and AUXn by opening electric switching circuit 182a, 182b, and 182d, as the test mode is focused on channel AUX1 at this time. With electric switching circuit 180c closed, current source 178c sends its fixed current through resistor 170c, terminal 124d, resistor divider 136c, 140c, and NTC resistor 130c, as well as all cabling, wiring, traces, and conduits between these devices. If all devices, cabling, wiring, traces, and conduits are fully functional and working properly, a voltage will be developed at node 172c that is within an acceptable range. The acceptable range is determined by the expected values of resistor 170c, resistor divider 136c, 140c, and NTC resistor 130c, as well as the resistance of all cabling, wiring, traces, and conduits between these devices and the known current from current source 178c. Typical values of resistance looking into NTC thermistor array 62 and cabling 64 may be 1.0-11.0 Kohms. In one embodiment, the acceptable range for the voltage developed at node 172c is 100 mV to 1.1 V. With electric switching circuit 182c closed, the same voltage will appear at node 184. The voltage at node 184 is routed through low voltage multiplexor 164 and converted to a digital value by ADC 166. The digital value is stored in Aux register 168. BMS 60 can read Aux register 168 and determine that there is no fault on channel AUX1 because the digital value of the voltage from node 172c is within the acceptable range.

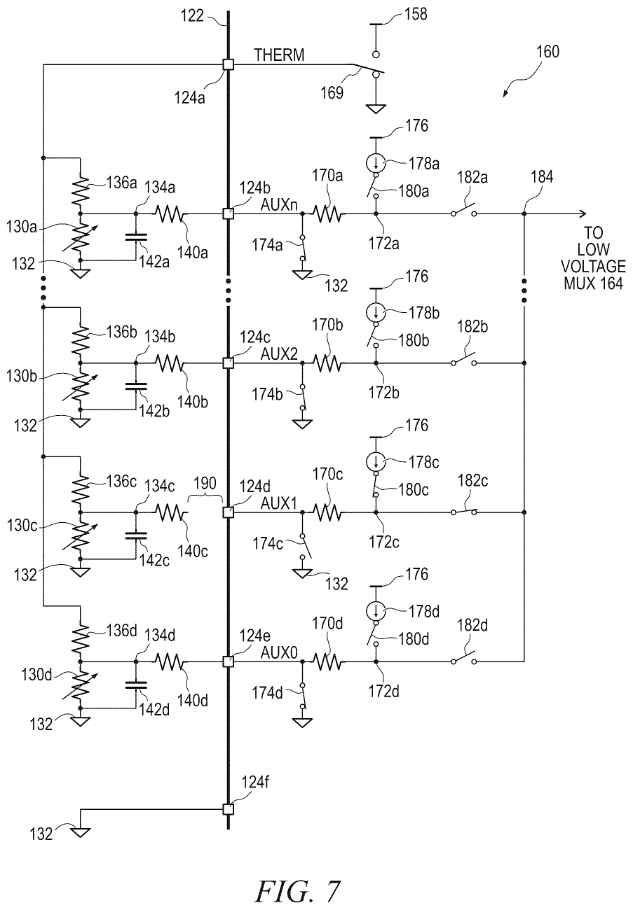

Next consider a fault condition on channel AUX1, i.e., an open circuit. In FIG. 7, an exemplary open circuit 190 is shown between resistor 140c and terminal 124d. With electric switching circuit 180c closed, current source 178c attempts to send its fixed current through resistor 170c, terminal 124d, resistor divider 136c, 140c, and NTC resistor 130c, as well as all cabling, wiring, traces, and conduits between these devices. However, open circuit 190 will block the current, due to the open circuit fault condition. In this case, a voltage will be developed at node 172c that is substantially equal to power supply conductor 176. In the open circuit fault condition, the voltage developed at node 172c is above the acceptable range. With electric switching circuit 182c closed, the same voltage will appear at node 184. The voltage at node 184 is routed through low voltage multiplexor 164 and converted to a digital value by ADC 166. The digital value is stored in Aux register 168. BMS 60 can read Aux register 168 and determine that there is a fault condition on channel AUX1, and further know that the fault is an open circuit, because the digital value of the voltage from node 172c is above the acceptable range.

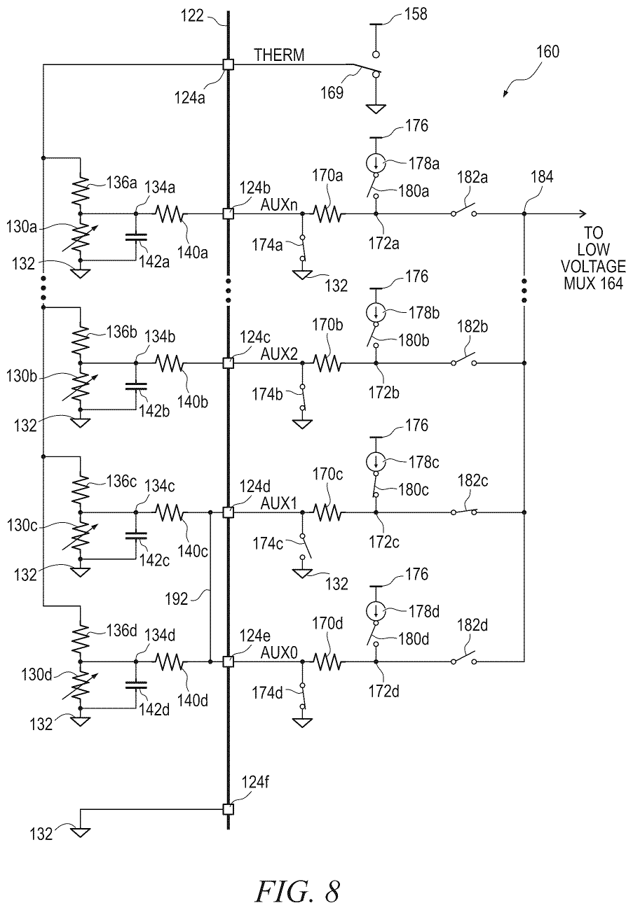

Next consider another fault condition on channel AUX1, i.e., a short circuit. In FIG. 8, an exemplary short circuit 192 is shown between terminal 124d and terminal 124e. With electric switching circuit 180c closed, current source 178c attempts to send its fixed current through resistor 170c, terminal 124d, resistor divider 136c, 140c, and NTC resistor 130c, as well as all cabling, wiring, traces, and conduits between these devices. However, short circuit 192 will route the current through electric switching circuit 174d to power supply conductor 132 operating at ground potential, due to the short circuit fault condition. In this case, a voltage will be developed at node 172c that is substantially equal to voltage across resistor 170c, i.e., close to ground. In the short circuit fault condition, the voltage developed at node 172c is below the acceptable range. With electric switching circuit 182c closed, the same voltage will appear at node 184. The voltage at node 184 is routed through low voltage multiplexor 164 and converted to a digital value by ADC 166. The digital value is stored in Aux register 168. BMS 60 can read Aux register 168 and determine that there is a fault condition on channel AUX1, and further know that the fault is a short circuit, because the digital value of the voltage from node 172c is below the acceptable range.

The above fault detection is directed to channel AUX1 in its test mode. Channels AUX0, AUX2, and AUXn were disabled during the test of channel AUX1. The test of channel AUX1 would reveal either no fault detected with the voltage at node 184 within the acceptable range, or a fault detected (open circuit or short circuit) as the voltage at node 184 is above or below the acceptable range. By using individual and sequential test modes for each channel AUX, fault detection and auxiliary GPIO multiplexor 160 can detect a fault anywhere along each AUX signal path, both external to semiconductor die 104 as well as internal to semiconductor die 104, up to nodes 172a, 172b, 172c, and 172d.

As for further disclosure on the acceptable range, assertion of an ALRTDIAGOVn (overvoltage) bit (DIAGn>AUXRDIAGOVTH) generally indicates a broken or high impedance external AUXn sense-wire path/port/bond-wire, resulting in an excessive level of deflection when the test current is applied. Assertion of an ALRTDIAGUVn (undervoltage) bit (DIAGn<AUXRDIAGUVTH) generally indicates a shorted AUXn sense-wire path/port/bondwire, or a broken test current source switch or broken internal connection to the AUXn port, preventing the expected level of deflection when the test current is applied.

The threshold AUXRDIAGUVTH is determined by either the fault case of an AUX measurement being pulled to ground (which will occur in a port-to-port short or a broken test current source) or the minimum allowable AUX measurement in a non-fault scenario. Whichever of these values is larger, that value should be chosen as the undervoltage threshold. Thus, the equivalent AUXRDIAGUVTH in units of voltage can be determined by in equation (3):

$${V}_{AUXRDIAGUVTH} = MAX \{ \begin{matrix}( {RESD}_{MAX} + {RTRACE}_{MAX} ) * {I}_{{AUXTST}_{MAX}} + noise \\ or \\ [ ( {RTHERM}_{MIN} ‖ {RNTC}_{MIN} ) + {RFILT}_{MIN} + {RESD}_{MIN} + {RTRACE}_{MIN} ] * {I}_{{AUXTST}_{MIN}} - noise\end{matrix} \qquad ( 3 )$$

where:
RESD+RTRACE is the resistance of resistor 170
IAUXTST is the current value of current source 178
RFILT is the resistance of resistor 140
RNTC is the resistance of thermistor 130
RTHERM is the resistance of resistor 136

(RESD+RTRACE) represents the shared impedance between the AUX test current source, and the AUX path trace to the pin. The “_{MIN}” and “_{MAX}” subscripts respectively, indicate the minimum and maximum allowable range of the named resistance or current. Thus, if the AUX voltage measured at the ADC were to ever fall below V_{AUXRDIAGUVTH}, this would represent the fault-case in which either the AUX pin is shorted to an adjacent grounded pin, or the internal test current itself has a broken connection. It should be noted that to get optimal fault coverage, the value of (RESD_{MAX}+RTRACE_{MAX}) should be minimized. This can be accomplished by various methods, such as simply using thicker traces or by connecting the AUX test current sources to their respective pins through separate Kelvin connections.

The threshold AUXRDIAGOVTH is determined by the maximum allowable AUX measurement voltage in a non-fault scenario. The calculation of V_{AUXRDIAGOVTH} includes the maximum allowable impedances of the connected NTC network, as in equation (4):

$${V}_{AUXRDIAGOVTH} = [ ( {RTHERM}_{MAX} ‖ {RNTC}_{MAX} ) + {RFILT}_{MAX} + {RESD}_{MAX} + {RTRACE}_{MAX} ] * {I}_{{AUXTST}_{MAX}} + noise \qquad ( 4 )$$

Thus, if the AUX voltage measured at the ADC were to exceed V_{AUXRDIAGOVTH}, this would represent the fault-case in which a High-Z or open path fault has occurred with the AUX path/pin in question.

The programmable code values of AUXRDIAGOVTH & AUXRDIAGUVTH (in decimal format) are simply determined by the following equation (5) and equation (6):

$$AUXRDIAGUVTH = \frac{{V}_{AUXRDIAGUVTH}}{{V}_{REF}} * ( {2}^{bits} - 1 ) \qquad ( 5 )$$

$$AUXRDIAGOVTH = \frac{{V}_{AUXRDIAGOVTH}}{{V}_{REF}} * ( {2}^{bits} - 1 ) \qquad ( 6 )$$

where V_{REF} is the internal reference voltage being used by the ADC, and
“bits” is number of bits resolved by the ADC.

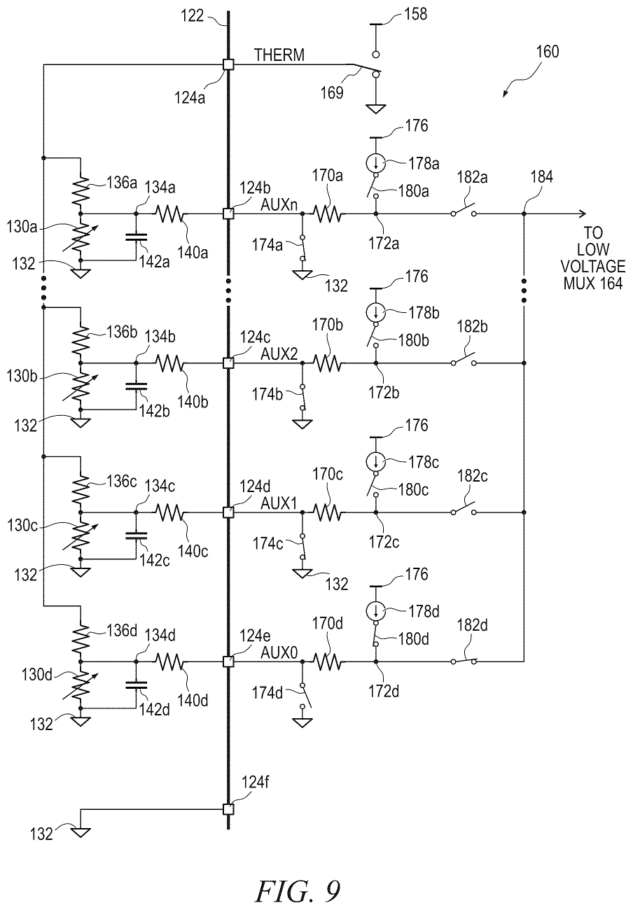

Now channel AUX0 is tested for a fault detection in its test mode. Electric switch circuit 169 may be set to ground terminal 124a thereby pulling all connected NTC networks and AUX pins resistively to ground. Electric switching circuit 182d is closed and electric switching circuits 182a, 182b, and 182c are open, as shown in FIG. 9. Electric switching circuit 174d is open and electric switching circuits 174a, 174b, and 174c are closed. Electric switching circuit 180d is closed and electric switching circuits 180a, 180b, and 180c are open. This configuration will perform fault detection in a test mode for channel AUX0 involving NTC resistor 130d, voltage divider resistors 136d, 140d, terminal 124e, resistor 170d, current source 178d, electric switching circuit 180d, and electric switching circuit 182d, as well as all cabling, wiring, traces, and conduits between these devices. The configuration disables fault detection for channels AUX1, AUX2, and AUXn by opening electric switching circuit 182a, 182b, and 182c, as the test is focused on channel AUX0 at this time. With electric switching circuit 180d closed, current source 178d sends its fixed current through resistor 170d, terminal 124e, resistor divider 136d, 140d, and NTC resistor 130d, as well as all cabling, wiring, traces, and conduits between these devices. If all devices, cabling, wiring, traces, and conduits are fully functional and working properly, a voltage will be developed at node 172d that is within the afore-described acceptable range. With electric switching circuit 182d closed, the same voltage will appear at node 184. The voltage at node 184 is routed through low voltage multiplexor 164 and converted to a digital value by ADC 166. The digital value is stored in Aux register 168. BMS 60 can read Aux register 168 and determine that there is no fault on channel AUX0 because the digital value of the voltage from node 172d is within the acceptable range.

Next consider a fault condition on channel AUX0, i.e., an open circuit. The open circuit would be similar to FIG. 7, e.g., an open between resistor 140d and terminal 124e. With electric switching circuit 180d closed, current source 178d attempts to send its fixed current through resistor 170d, terminal 124e, resistor divider 136d, 140d, and NTC resistor 130d, as well as all cabling, wiring, traces, and conduits between these devices. However, the open circuit fault condition will block the current. In this case, a voltage will be developed at node 172d that is substantially equal to power supply conductor 176. In the open circuit fault condition, the voltage developed at node 172d is above the acceptable range. With electric switching circuit 182d closed, the same voltage will appear at node 184. The voltage at node 184 is routed through low voltage multiplexor 164 and converted to a digital value by ADC 166. The digital value is stored in Aux register 168. BMS 60 can read Aux register 168 and determine that there is a fault condition on channel AUX0, and further know that the fault is an open circuit, because the digital value of the voltage from node 172d is above the acceptable range.

Next consider another fault condition on channel AUX0, i.e., a short circuit. The short circuit would be similar to FIG. 8, with a short circuit between terminal 124d and terminal 124e. With electric switching circuit 180d closed, current source 178d attempts to send its fixed current through resistor 170d, terminal 124e, resistor divider 136d, 140d, and NTC resistor 130d, as well as all cabling, wiring, traces, and conduits between these devices. However, the short circuit fault condition will route the current through electric switching circuit 174c to power supply conductor 132 operating at ground potential. In this case, a voltage will be developed at node 172d that is substantially equal to voltage across resistor 170d, i.e., close to ground. In the short circuit fault condition, the voltage developed at node 172d is below the acceptable range. With electric switching circuit 182d closed, the same voltage will appear at node 184. The voltage at node 184 is routed through low voltage multiplexor 164 and converted to a digital value by ADC 166. The digital value is stored in Aux register 168. BMS 60 can read Aux register 168 and determine that there is a fault condition on channel AUX0, and further know that the fault is a short circuit, because the digital value of the voltage from node 172d is below the acceptable range.

The above fault detection is directed to channel AUX0 in its test mode. Channels AUX1, AUX2, and AUXn were disabled during the test of channel AUX0. The test of channel AUX0 would reveal either no fault detected with the voltage at node 184 within the acceptable range, or a fault detected (open circuit or short circuit) as the voltage at node 184 is above or below the acceptable range. By using individual and sequential test modes for each channel AUX, fault detection and auxiliary GPIO multiplexor 160 can detect a fault anywhere along each AUX signal path, both external to semiconductor die 104 as well as internal to semiconductor die 104, up to nodes 172a, 172b, 172c, and 172d.

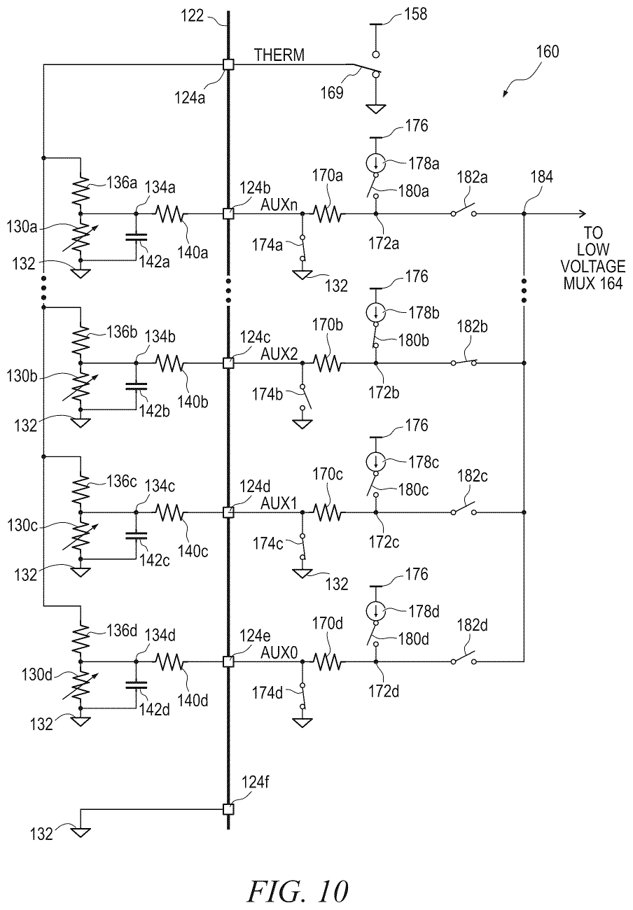

Now channel AUX2 is tested for a fault detection its test mode. Electric switch circuit 169 may be set to ground terminal 124a thereby pulling all connected NTC networks and AUX pins resistively to ground. Electric switching circuit 182b is closed and electric switching circuits 182a, 182c, and 182d are open, as shown in FIG. 10. Electric switching circuit 174b is open and electric switching circuits 174a, 174c, and 174d are closed. Electric switching circuit 180b is closed and electric switching circuits 180a, 180c, and 180d are open. This configuration will perform fault detection in a test mode for channel AUX2 involving NTC resistor 130b, voltage divider resistors 136b, 140b, terminal 124c, resistor 170b, current source 178b, electric switching circuit 180b, and electric switching circuit 182b, as well as all cabling, wiring, traces, and conduits between these devices. The configuration disables fault detection for channels AUX0, AUX1, and AUXn by opening electric switching circuit 182a, 182c, and 182d, as the test is focused on channel AUX2 at this time. With electric switching circuit 180b closed, current source 178b sends its fixed current through resistor 170b, terminal 124c, resistor divider 136b, 140b, and NTC resistor 130b, as well as all cabling, wiring, traces, and conduits between these devices. If all devices, cabling, wiring, traces, and conduits are fully functional and working properly, a voltage will be developed at node 172b that is within the afore-described acceptable range. With electric switching circuit 182b closed, the same voltage will appear at node 184. The voltage at node 184 is routed through low voltage multiplexor 164 and converted to a digital value by ADC 166. The digital value is stored in Aux register 168. BMS 60 can read Aux register 168 and determine that there is no fault on channel AUX2 because the digital value of the voltage from node 172b is within the acceptable range.

Next consider a fault condition on channel AUX2, i.e., an open circuit. The open circuit would be similar to FIG. 7, e.g., an open between resistor 140b and terminal 124c. With electric switching circuit 180b closed, current source 178b attempts to send its fixed current through resistor 170b, terminal 124c, resistor divider 136b, 140b, and NTC resistor 130b, as well as all cabling, wiring, traces, and conduits between these devices. However, the open circuit fault condition will block the current. In this case, a voltage will be developed at node 172b that is substantially equal to power supply conductor 176. In the open circuit fault condition, the voltage developed at node 172b is above the acceptable range. With electric switching circuit 182b closed, the same voltage will appear at node 184. The voltage at node 184 is routed through low voltage multiplexor 164 and converted to a digital value by ADC 166. The digital value is stored in Aux register 168. BMS 60 can read Aux register 168 and determine that there is a fault condition on channel AUX2, and further know that the fault is an open circuit, because the digital value of the voltage from node 172b is above the acceptable range.

Next consider another fault condition on channel AUX2, i.e., a short circuit. The short circuit would be similar to FIG. 8, with a short circuit between terminal 124c and terminal 124d. With electric switching circuit 180b closed, current source 178b attempts to send its fixed current through resistor 170b, terminal 124c, resistor divider 136b, 140b, and NTC resistor 130b, as well as all cabling, wiring, traces, and conduits between these devices. However, the short circuit fault condition will route the current through electric switching circuit 174c to power supply conductor 132 operating at ground potential. In this case, a voltage will be developed at node 172b that is substantially equal to voltage across resistor 170b, i.e., close to ground. In the short circuit fault condition, the voltage developed at node 172b is below the acceptable range. With electric switching circuit 182b closed, the same voltage will appear at node 184. The voltage at node 184 is routed through low voltage multiplexor 164 and converted to a digital value by ADC 166. The digital value is stored in Aux register 168. BMS 60 can read Aux register 168 and determine that there is a fault condition on channel AUX2, and further know that the fault is a short circuit, because the digital value of the voltage from node 172b is below the acceptable range.

The above fault detection is directed to channel AUX2 in its test mode. Channels AUX0, AUX1, and AUXn were disabled during the test of channel AUX2. The test of channel AUX2 would reveal either no fault detected with the voltage at node 184 within the acceptable range, or a fault detected (open circuit or short circuit) as the voltage at node 184 is above or below the acceptable range. By using individual and sequential test modes for each channel AUX, fault detection and auxiliary GPIO multiplexor 160 can detect a fault anywhere along each AUX signal path, both external to semiconductor die 104 as well as internal to semiconductor die 104, up to nodes 172a, 172b, 172c, and 172d.

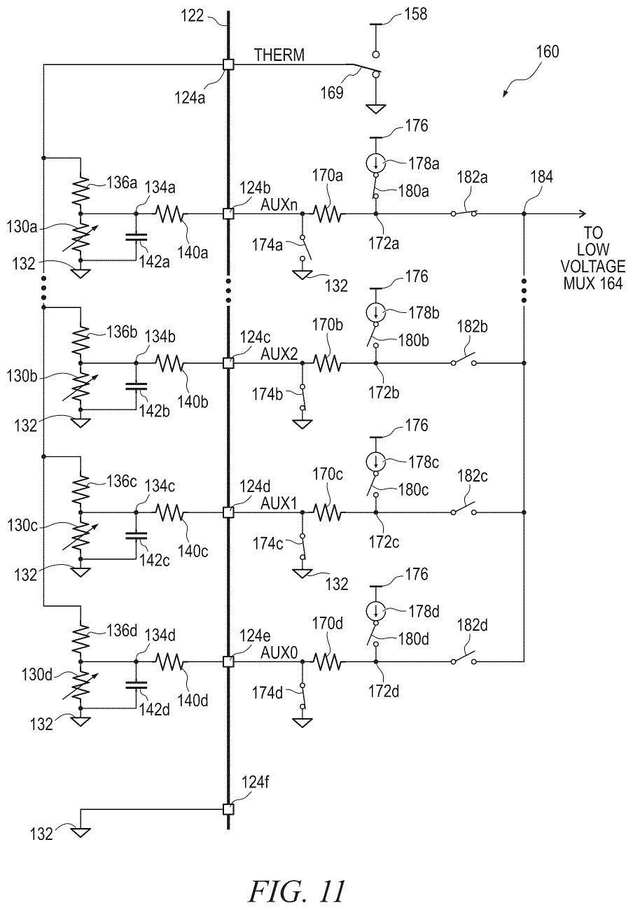

Now channel AUXn is tested for a fault detection its test mode. Electric switch circuit 169 may be set to ground terminal 124a thereby pulling all connected NTC networks and AUX pins resistively to ground. Electric switching circuit 182a is closed and electric switching circuits 182a, 182b, and 182c are open, as shown in FIG. 11. Electric switching circuit 174a is open and electric switching circuits 174b, 174c, and 174d are closed. Electric switching circuit 180a is closed and electric switching circuits 180b, 180c, and 180d are open. This configuration will perform fault detection in a test mode for channel AUXn involving NTC resistor 130a, voltage divider resistors 136a, 140a, terminal 124b, resistor 170a, current source 178a, electric switching circuit 180a, and electric switching circuit 182a, as well as all cabling, wiring, traces, and conduits between these devices. The configuration disables fault detection for channels AUX0, AUX1, and AUX2 by opening electric switching circuit 182b, 182c, and 182d, as the test is focused on channel AUXn at this time. With electric switching circuit 180a closed, current source 178a sends its fixed current through resistor 170a, terminal 124b, resistor divider 136a, 140a, and NTC resistor 130a, as well as all cabling, wiring, traces, and conduits between these devices. If all devices, cabling, wiring, traces, and conduits are fully functional and working properly, a voltage will be developed at node 172a that is within the afore-described acceptable range. With electric switching circuit 182a closed, the same voltage will appear at node 184. The voltage at node 184 is routed through low voltage multiplexor 164 and converted to a digital value by ADC 166. The digital value is stored in Aux register 168. BMS 60 can read Aux register 168 and determine that there is no fault on channel AUXn because the digital value of the voltage from node 172a is within the acceptable range.

Next consider a fault condition on channel AUXn, i.e., i.e., open circuit. The open circuit would be similar to FIG. 7, e.g., an open between resistor 140a and terminal 124b. With electric switching circuit 180a closed, current source 178a attempts to send its fixed current through resistor 170a, terminal 124b, resistor divider 136a, 140a, and NTC resistor 130a, as well as all cabling, wiring, traces, and conduits between these devices. However, the open circuit fault condition will block the current. In this case, a voltage will be developed at node 172a that is substantially equal to power supply conductor 176. In the open circuit fault condition, the voltage developed at node 172a is above the acceptable range. With electric switching circuit 182a closed, the same voltage will appear at node 184. The voltage at node 184 is routed through low voltage multiplexor 164 and converted to a digital value by ADC 166. The digital value is stored in Aux register 168. BMS 60 can read Aux register 168 and determine that there is a fault condition on channel AUXn, and further know that the fault is an open circuit, because the digital value of the voltage from node 172a is above the acceptable range.

Next consider another fault condition on channel AUXn, i.e., a short circuit. The short circuit would be similar to FIG. 8, with a short circuit between terminal 124b and terminal 124c. With electric switching circuit 180a closed, current source 178a attempts to send its fixed current through resistor 170a, terminal 124b, resistor divider 136a, 140a, and NTC resistor 130a, as well as all cabling, wiring, traces, and conduits between these devices. However, the short circuit fault condition will route the current through electric switching circuit 174b to power supply conductor 132 operating at ground potential. In this case, a voltage will be developed at node 172a that is substantially equal to voltage across resistor 170a, i.e., close to ground. In the short circuit fault condition, the voltage developed at node 172a is below the acceptable range. With electric switching circuit 182a closed, the same voltage will appear at node 184. The voltage at node 184 is routed through low voltage multiplexor 164 and converted to a digital value by ADC 166. The digital value is stored in Aux register 168. BMS 60 can read Aux register 168 and determine that there is a fault condition on channel AUXn, and further know that the fault is a short circuit, because the digital value of the voltage from node 172a is below the acceptable range.

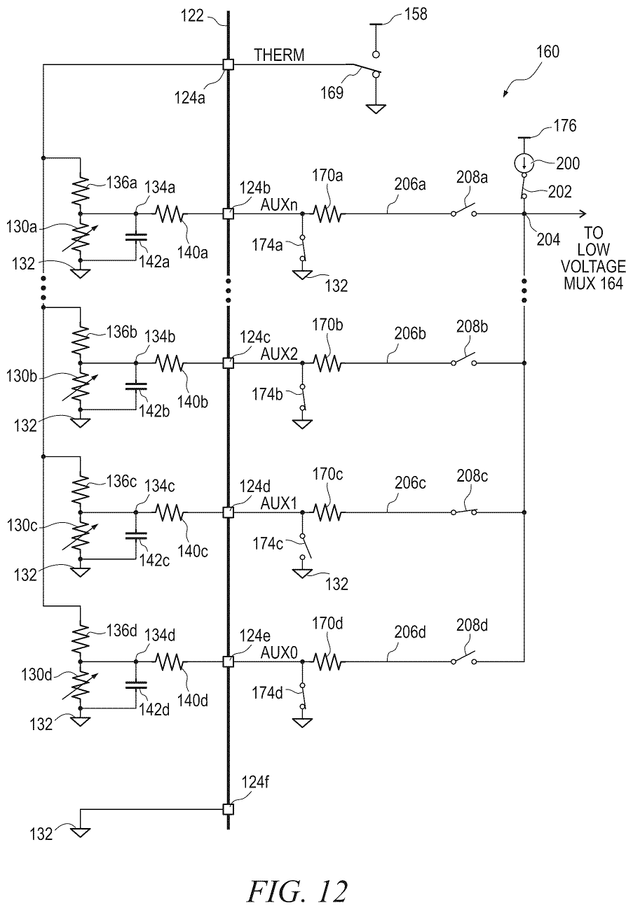

Another embodiment of fault detection and auxiliary GPIO multiplexor 160 is shown in FIG. 12. In this particular embodiment, current sources 178 are disconnected by opening electrical switching circuit 180, effectively removing them from the operation. Instead, current source 200, as referenced to power supply conductor 176 operating at a positive potential, sources a fixed current. Electric switching circuit 202 is coupled between current source 200 and node 204. Electric switching circuit 208a is coupled between node 206a and node 204, electrical switching circuit 208b is coupled between node 206b and node 204, electrical switching circuit 208c is coupled between node 206c and node 204, and electrical switching circuit 208d is coupled between node 206d and node 204. Otherwise, elements or components having a similar function are assigned the same reference number.

Channel AUX1 is tested for a fault detection its test mode. Electric switch circuit 169 may be set to ground terminal 124a thereby pulling all connected NTC networks and AUX pins resistively to ground. Electric switching circuit 208c is closed and electric switching circuits 208a, 208b, and 208d are open, as shown in FIG. 12. Electric switching circuit 174c is open and electric switching circuits 174a, 174b, and 174d are closed. Electric switching circuit 202 is closed. This configuration will perform fault detection in a test mode for channel AUX1 involving NTC resistor 130c, voltage divider resistors 136c, 140c, terminal 124d, resistor 170c, electric switching circuit 208c, current source 200, and electric switching circuit 202, and, as well as all cabling, wiring, traces, and conduits between these devices. The configuration disables fault detection for channels AUX0, AUX2, and AUXn by opening electric switching circuit 208a, 208b, and 208d, as the test is focused on channel AUX1 at this time. With electric switching circuit 208c closed, current source 200 sends its fixed current through resistor 170c, terminal 124d, resistor divider 136c, 140c, and NTC resistor 130c, as well as all cabling, wiring, traces, and conduits between these devices. If all devices, cabling, wiring, traces, and conduits are fully functional and working properly, a voltage will be developed at node 206c that is within the afore-described acceptable range. With electric switching circuit 208c closed, the same voltage will appear at node 204. The voltage at node 204 is routed through low voltage multiplexor 164 and converted to a digital value by ADC 166. The digital value is stored in Aux register 168. BMS 60 can read Aux register 168 and determine that there is no fault on channel AUX1 because the digital value of the voltage from node 206c is within the acceptable range.

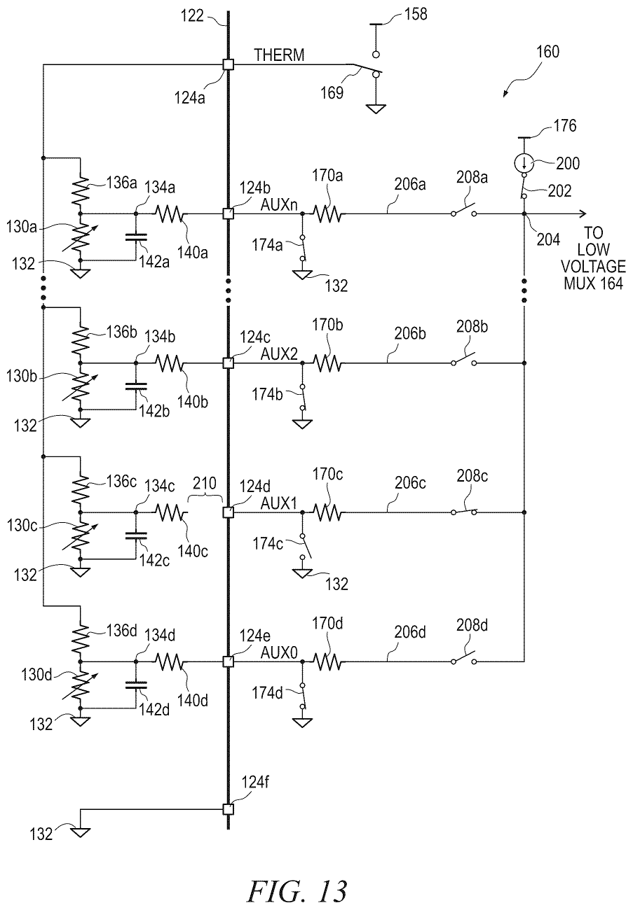

Next consider a fault condition on channel AUX1, i.e., an open circuit. The open circuit would be similar to FIG. 7, e.g., an exemplary open 210 between resistor 140c and terminal 124d in FIG. 13. The open circuit could also be internal to semiconductor die 104, along the AUX1 path up to node 204. The open circuit could be internal to semiconductor die 104. With electric switching circuit 202 closed, current source 200 attempts to send its fixed current through resistor 170c, terminal 124d, resistor divider 136c, 140c, and NTC resistor 130c, as well as all cabling, wiring, traces, and conduits between these devices. However, the open circuit fault condition will block the current. In this case, a voltage will be developed at node 206c that is substantially equal to power supply conductor 176. In the open circuit fault condition, the voltage developed at node 206c is above the acceptable range. With electric switching circuit 208c closed, the same voltage will appear at node 204. The voltage at node 204 is routed through low voltage multiplexor 164 and converted to a digital value by ADC 166. The digital value is stored in Aux register 168. BMS 60 can read Aux register 168 and determine that there is a fault condition on channel AUX1, and further know that the fault is an open circuit, because the digital value of the voltage from node 206c is above the acceptable range.

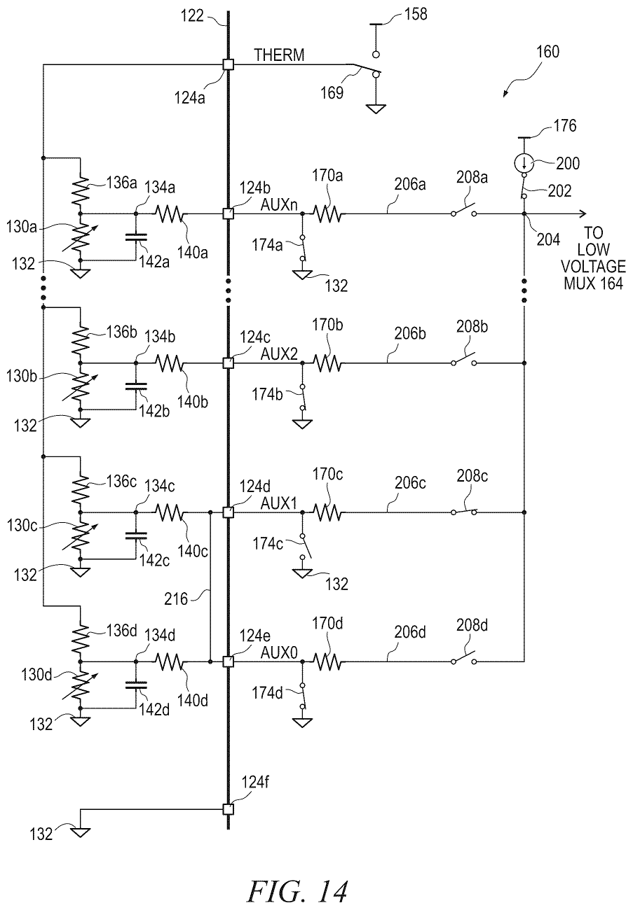

Next consider another fault condition on channel AUX1, i.e., a short circuit. The short circuit would be similar to FIG. 8, with a short circuit 216 between terminal 124d and terminal 124e in FIG. 14. With electric switching circuit 202 closed, current source 200 attempts to send its fixed current through resistor 170c, terminal 124d, resistor divider 136c, 140c, and NTC resistor 130c, as well as all cabling, wiring, traces, and conduits between these devices. However, the short circuit fault condition will route the current through electric switching circuit 174d to power supply conductor 132 operating at ground potential. In this case, a voltage will be developed at node 206c that is substantially equal to voltage across resistor 170c, i.e., close to ground. In the short circuit fault condition, the voltage developed at node 206c is below the acceptable range. With electric switching circuit 208c closed, the same voltage will appear at node 204. The voltage at node 204 is routed through low voltage multiplexor 164 and converted to a digital value by ADC 166. The digital value is stored in Aux register 168. BMS 60 can read Aux register 168 and determine that there is a fault condition on channel AUX1, and further know that the fault is a short circuit, because the digital value of the voltage from node 206c is below the acceptable range.

The above fault detection is directed to channel AUX1 in its test mode. Channels AUX0, AUX2, and AUXn were disabled during the test of channel AUX1. The test of channel AUX1 would reveal either no fault detected with the voltage at node 204 within the acceptable range, or a fault detected (open circuit or short circuit) as the voltage at node 204 is above or below the acceptable range. By using individual and sequential test modes for each channel AUX, fault detection and auxiliary GPIO multiplexor 160 can detect a fault anywhere along each AUX signal path, both external to semiconductor die 104 as well as internal to semiconductor die 104, up to node 204.

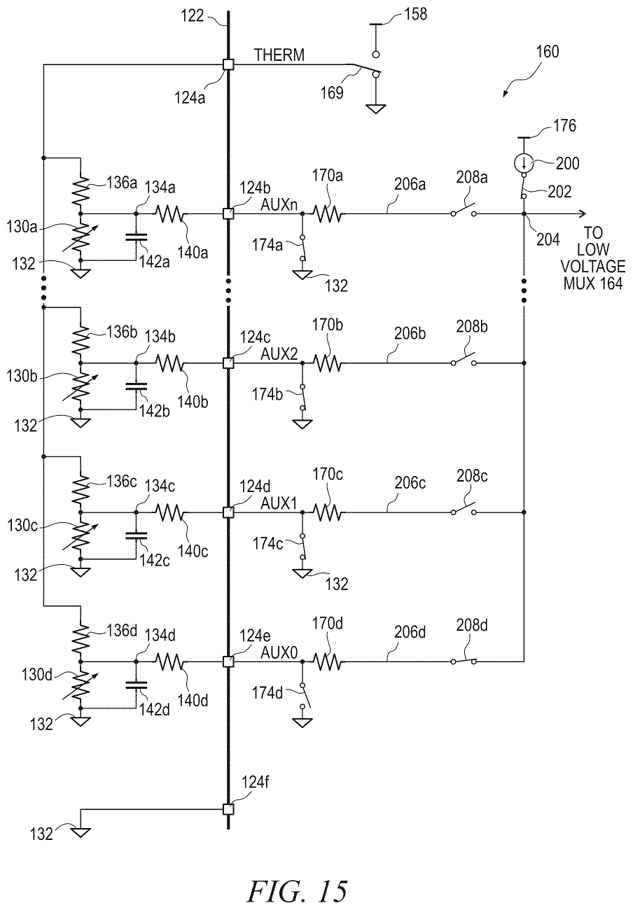

Now channel AUX0 is tested for a fault detection in its test mode. Electric switch circuit 169 may be set to ground terminal 124a thereby pulling all connected NTC networks and AUX pins resistively to ground. Electric switching circuit 208d is closed and electric switching circuits 208a, 208b, and 208c are open, as shown in FIG. 15. Electric switching circuit 174d is open and electric switching circuits 174a, 174b, and 174c are closed. Electric switching circuit 202 is closed. This configuration will perform fault detection in a test mode for channel AUX0 involving NTC resistor 130d, voltage divider resistors 136d, 140d, terminal 124e, resistor 170d, electric switching circuit 208d, current source 200, and electric switching circuit 202, as well as all cabling, wiring, traces, and conduits between these devices. The configuration disables fault detection for channels AUX1, AUX2, and AUXn by opening electric switching circuit 208a, 208b, and 208c, as the test is focused on channel AUX0 at this time. With electric switching circuit 208d closed, current source 200 sends its fixed current through resistor 170d, terminal 124e, resistor divider 136d, 140d, and NTC resistor 130d, as well as all cabling, wiring, traces, and conduits between these devices. If all devices, cabling, wiring, traces, and conduits are fully functional and working properly, a voltage will be developed at node 206d that is within the afore-described acceptable range. With electric switching circuit 208d closed, the same voltage will appear at node 204. The voltage at node 204 is routed through low voltage multiplexor 164 and converted to a digital value by ADC 166. The digital value is stored in Aux register 168. BMS 60 can read Aux register 168 and determine that there is no fault on channel AUX0 because the digital value of the voltage from node 206d is within the acceptable range.

Next consider a fault condition on channel AUX0, i.e., an open circuit. The open circuit would be similar to FIG. 13, e.g., an open between resistor 140d and terminal 124e. With electric switching circuit 202 closed, current source 200 attempts to send its fixed current through resistor 170d, terminal 124e, resistor divider 136d, 140d, and NTC resistor 130d, as well as all cabling, wiring, traces, and conduits between these devices. However, the open circuit fault condition will block the current. In this case, a voltage will be developed at node 206d that is substantially equal to power supply conductor 176. In the open circuit fault condition, the voltage developed at node 206d is above the acceptable range. With electric switching circuit 208d closed, the same voltage will appear at node 204. The voltage at node 204 is routed through low voltage multiplexor 164 and converted to a digital value by ADC 166. The digital value is stored in Aux register 168. BMS 60 can read Aux register 168 and determine that there is a fault condition on channel AUX0, and further know that the fault is an open circuit, because the digital value of the voltage from node 206d is above the acceptable range.

Next consider another fault condition on channel AUX0, i.e., a short circuit. The short circuit would be similar to FIG. 14, with a short circuit between terminal 124d and terminal 124e. With electric switching circuit 202 closed, current source 200 attempts to send its fixed current through resistor 170d, terminal 124e, resistor divider 136d, 140d, and NTC resistor 130d, as well as all cabling, wiring, traces, and conduits between these devices. However, the short circuit fault condition will route the current through electric switching circuit 174c to power supply conductor 132 operating at ground potential. In this case, a voltage will be developed at node 206d that is substantially equal to voltage across resistor 170d, i.e., close to ground. In the short circuit fault condition, the voltage developed at node 206d is below the acceptable range. With electric switching circuit 208d closed, the same voltage will appear at node 204. The voltage at node 204 is routed through low voltage multiplexor 164 and converted to a digital value by ADC 166. The digital value is stored in Aux register 168. BMS 60 can read Aux register 168 and determine that there is a fault condition on channel AUX0, and further know that the fault is a short circuit, because the digital value of the voltage from node 206d is below the acceptable range.

The above fault detection is directed to channel AUX0 in its test mode. Channels AUX1, AUX2, and AUXn were disabled during the test of channel AUX0. The test of channel AUX1 would reveal either no fault detected with the voltage at node 204 within the acceptable range, or a fault detected (open circuit or short circuit) as the voltage at node 204 is above or below the acceptable range. By using individual and sequential test modes for each channel AUX, fault detection and auxiliary GPIO multiplexor 160 can detect a fault anywhere along each AUX signal path, both external to semiconductor die 104 as well as internal to semiconductor die 104, up to node 204.

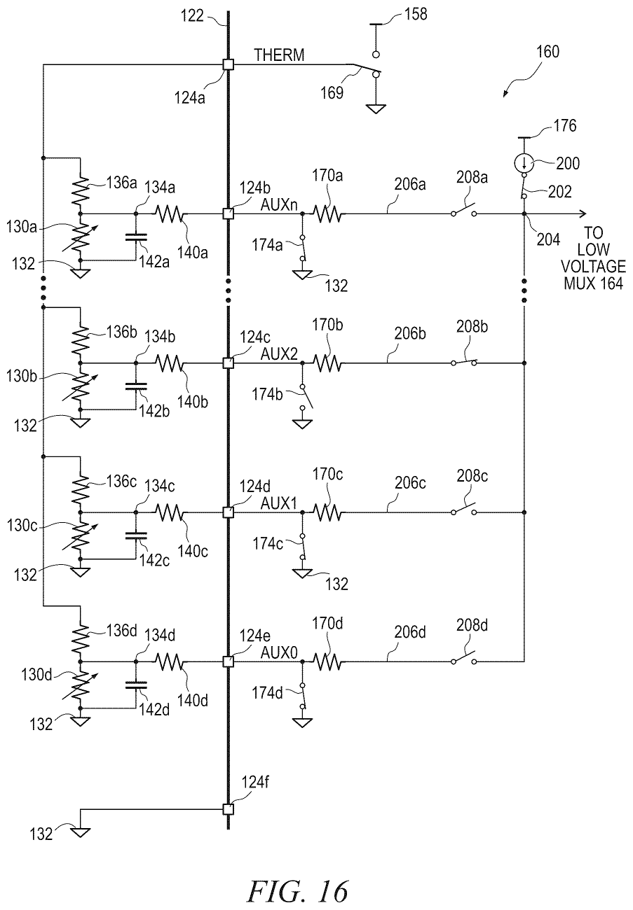

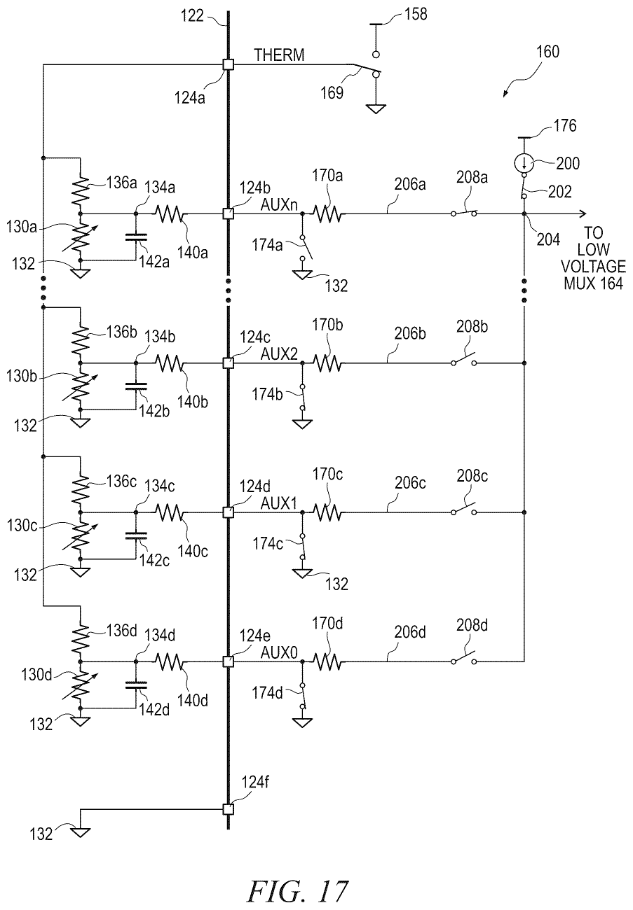

Similar test modes are performed individually for channel AUX2, as in FIG. 16, and channel AUXn, as in FIG. 17. The explanation has been covered multiple times. The test of channel AUX2 would reveal either no fault detected with the voltage at node 204 within the acceptable range, or a fault detected (open circuit or short circuit) as the voltage at node 204 is above or below the acceptable range. The test of channel AUXn would reveal either no fault detected with the voltage at node 204 within the acceptable range, or a fault detected (open circuit or short circuit) as the voltage at node 204 is above or below the acceptable range.

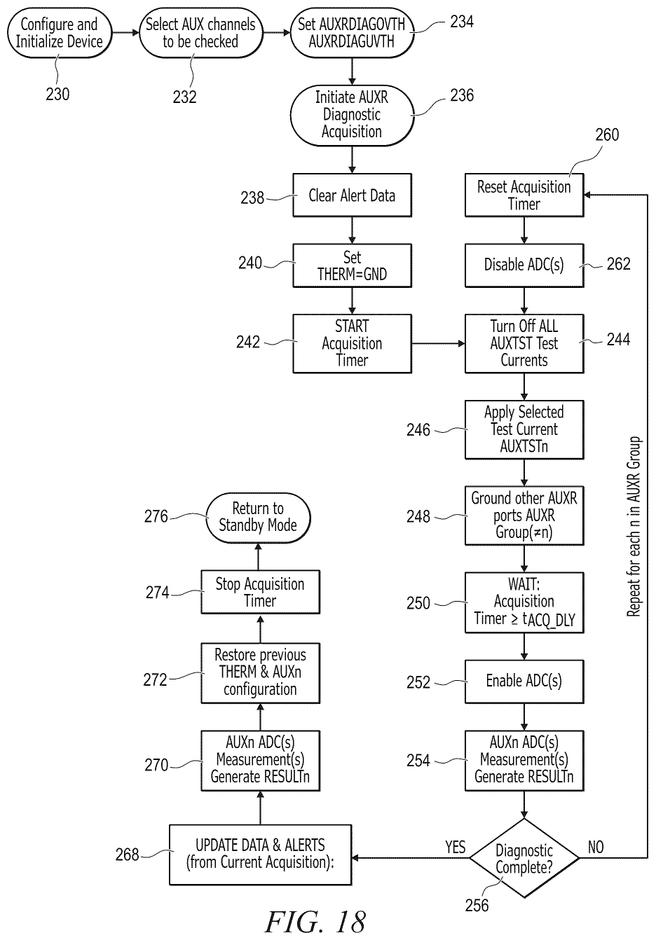

FIG. 18 provides a flow chart 220 summarizing the fault testing for channels AUX0-AUXn. In step 230, the device is configured and initialized. In step 232, AUX channels to be tested are selected. In step 234, AUXRDIAGOVTH and AUXRDIAGUVTH are set. In step 236, AUXR diagnostic acquisition is initialized. In step 238, fault alert data is cleared. In step 240, electric switching circuit 169 may be set to ground terminal 124a to pull all connected NTC networks and AUX pins resistively to ground. the devices to be tested. In step 242, an acquisition timer is started. In step 244, current sources are turned off. In step 246, the current source associated with the test mode is enabled. In step 248, non-testing AUX channels are grounded with appropriate electric switching circuit 174. In step 250, wait for acquisition. In step 252, enable ADC 166. In step 254, test AUX channel. In step 256, check for diagnostics complete. If no, reset acquisition timer in step 260, disable ADC 166 in step 262, and continue to step 244. If yes, update data and alerts in step 268, generate test results in step 270, restore previous THERM and AUXn channel configurations in step 272, stop acquisition timer in step 274, and return to standby mode in step 276. By using individual and sequential test modes for each channel AUX, fault detection and auxiliary GPIO multiplexor 160 can detect a fault anywhere along each AUX signal path, both external to semiconductor die 104 as well as internal to semiconductor die 104.

Further details are provided to assist with implementation. All checked AUX pins should be either adjacent to one another or bounded by grounded pins. During the diagnostic, ensure that any pins adjacent to the AUXn pins under test are pulled to ground. If a group of AUX pins is bounded by a logic pin with an output driven high, or an IO supply pin, the diagnostic may return a fault, but it may not be possible to distinguish between a broken AUXn connection and a short to the neighboring port. Each AUXn port to be checked should connect to an external resistor network as pictured in FIG. 3. FIG. 3 depicts the divider network with an NTC resistor; however, this approach works the same with any resistive divider network. If, for example, the user was attempting to drive an AUX pin with a voltage source (rather than a ratio-metric network), this automated diagnostic would need to be modified to account for the source impedance of the voltage source applied.

The diagnostic automatically executes a sequence of individual measurements on each ratio-metric AUXn port to be checked. The diagnostic sequence will initiate an automated setup and measurement for each AUXn port to be tested and will ultimately perform the following operations. The THERM port is shorted to GND during the entire diagnostic sequence to ensure that the entire NTC network is resistively pulled to ground through the R_{THERMn} and R_{NTCn} resistors. The required pull-up test current (AUXTSTn) is applied to the AUXn port under test. All other AUX #n ports are shorted to ground using GPIO≠n open drain NMOS pull-down switches. An ADC measurement of the voltage on AUXn port under test is performed. The above steps for each value of “n” in the AUX group is repeated. All results are digitally compared to both overvoltage threshold AUXRDIAGOVTH and undervoltage threshold AUXRDIAGUVTH. Assert alert ALRTDIAGOVn if RESULTn>AUXRDIAGOVTH. Assert alert ALRTDIAGUVn if RESULTn<AUXRDIAGUVTH. Once all selected AUXn pins have been checked, the diagnostic is complete, and the previous configuration of the AUXn pins will be restored.

In summary, the fault detection is an automated diagnostic method that efficiently detects and reports both port-to-port shorts as well as broken-wire faults within the same diagnostic acquisition. Furthermore, the specific fault and location of the fault can be determined by this diagnostic and readily provided to the user. Typically, this diagnostic requires a duration of less than 50 us per checked AUX channel, allowing the user very quick access to results. The diagnostic method is intended to be run periodically outside of times when the AUX pins are being measured in a typical ratio-metric or absolute acquisitions. By using individual and sequential test modes for each channel AUX, fault detection and auxiliary GPIO multiplexor 160 can detect a fault anywhere along each AUX signal path, both external to semiconductor die 104 as well as internal to semiconductor die 104.

While one or more embodiments of the present invention have been illustrated in detail, the skilled artisan will appreciate that modifications and adaptations to those embodiments may be made without departing from the scope of the present invention as set forth in the following claims.

What is claimed:

1. A fault detection circuit, comprising:
a plurality of inputs each adapted for coupling to a resistance network; and
a current source circuit selectively coupled to each of the plurality of inputs to detect a fault condition.

2. The fault detection circuit of claim 1, wherein the current source circuit includes:
a first current source;
a first switching circuit coupled between the first current source and a first node;
a first resistor coupled between the first node and a first input of the plurality of inputs;
a second switching circuit coupled between the first input and a power supply conductor; and
a third switching circuit coupled between the first node and a second node.

3. The fault detection circuit of claim 2, wherein a fault detection signal is generated at the second node.

4. The fault detection circuit of claim 2, wherein the current source circuit further includes:
a second current source;
a fourth switching circuit coupled between the second current source and a third node;
a second resistor coupled between the third node and a second input of the plurality of inputs;
a fifth switching circuit coupled between the second input and the power supply conductor; and
a sixth switching circuit coupled between the third node and the second node.

5. The fault detection circuit of claim 1, wherein the current source circuit includes:
a current source;
a first switching circuit coupled between the current source and a first node;
a first resistor coupled to a first input of the plurality of inputs;
a second switching circuit coupled between the first input and a power supply conductor; and
a third switching circuit coupled between the first resistor and the first node.

6. The fault detection circuit of claim 5, wherein the current source circuit further includes:
a second resistor coupled to a second input of the plurality of inputs;
a fourth switching circuit coupled between the second input and the power supply conductor; and
a fifth switching circuit coupled between the second resistor and the first node.

7. A semiconductor device, comprising:
a semiconductor die including a plurality of input terminals each adapted for coupling to a resistance network; and
a fault detection circuit formed on the semiconductor die, wherein the fault detection circuit includes a current source circuit selectively coupled to each of the plurality of input terminals to detect a fault condition.

8. The semiconductor device of claim 7, wherein the current source circuit includes:
a first current source;
a first switching circuit coupled between the first current source and a first node;
a first resistor coupled between the first node and a first input terminal of the plurality of input terminals;
a second switching circuit coupled between the first input and a power supply conductor; and
a third switching circuit coupled between the first node and a second node.

9. The semiconductor device of claim 8, wherein a fault detection signal is generated at the second node.

10. The semiconductor device of claim 9, wherein the fault detection signal indicates an open circuit or a short circuit.

11. The semiconductor device of claim 8, wherein the current source circuit further includes:
a second current source;
a fourth switching circuit coupled between the second current source and a third node;
a second resistor coupled between the third node and a second input terminal of the plurality of input terminals;
a fifth switching circuit coupled between the second input and the power supply conductor; and
a sixth switching circuit coupled between the third node and the second node.

12. The semiconductor device of claim 7, wherein the current source circuit includes:
a current source;
a first switching circuit coupled between the current source and a first node;
a first resistor coupled to a first input of the plurality of inputs;
a second switching circuit coupled between the first input and a power supply conductor; and
a third switching circuit coupled between the first resistor and the first node.

13. The semiconductor device of claim 11, wherein the current source circuit further includes:
a second resistor coupled to a second input terminal of the plurality of input terminals;
a fourth switching circuit coupled between the second input and the power supply conductor; and
a fifth switching circuit coupled between the second resistor and the first node.

14. A method of making a semiconductor device, comprising:
providing a semiconductor die including a plurality of input terminals each adapted for coupling to a resistance network; and
forming a fault detection circuit on the semiconductor die, wherein forming the fault detection circuit includes forming a current source circuit selectively coupled to each of the plurality of input terminals to detect a fault condition.

15. The method of claim 14, wherein forming the current source circuit includes:
providing a first current source;
providing a first switching circuit coupled between the first current source and a first node;
providing a first resistor coupled between the first node and a first input terminal of the plurality of input terminals;
providing a second switching circuit coupled between the first input and a power supply conductor; and
providing a third switching circuit coupled between the first node and a second node.

16. The method of claim 15, further including generating a fault detection signal at the second node.

17. The method of claim 16, wherein the fault detection signal indicates an open circuit or a short circuit.

18. The method of claim 15, wherein forming the current source circuit further includes:
providing a second current source;
providing a fourth switching circuit coupled between the second current source and a third node;
providing a second resistor coupled between the third node and a second input terminal of the plurality of input terminals;
providing a fifth switching circuit coupled between the second input and the power supply conductor; and
providing a sixth switching circuit coupled between the third node and the second node.

19. The method of claim 14, wherein forming the current source circuit includes:
providing a current source;
providing a first switching circuit coupled between the current source and a first node;
providing a first resistor coupled to a first input of the plurality of inputs;
providing a second switching circuit coupled between the first input and a power supply conductor; and
providing a third switching circuit coupled between the first resistor and the first node.

20. The method of claim 19, wherein forming the current source circuit further includes:
providing a second resistor coupled to a second input terminal of the plurality of input terminals;
providing a fourth switching circuit coupled between the second input and the power supply conductor; and
providing a fifth switching circuit coupled between the second resistor and the first node.
